(19) United States
(12) Patent Application Publication
(10) Pub. No.: US 2022/0393129 A1
(43) Pub. Date: Dec. 8, 2022

(54) LIGHT-EMITTING ELECTROCHEMICAL CELL AND ELECTROLUMINESCENT DISPLAY DEVICE

(71) Applicant: TCL China Star Optoelectronics Technology Co., Ltd, Shenzhen (CN)

(72) Inventor: Jinyang ZHAO, Shenzhen (CN)

(21) Appl. No.: 16/640,745

(22) PCT Filed: Jan. 13, 2020
(86) PCT No.: PCT/CN2020/071805

§ 371 Date: Feb. 21, 2020

(30) Foreign Application Priority Data
Dec. 26, 2019 (CN) 201911368117.4

(51) Int. Cl. H01L 51/50; H01L 27/32; H01L 51/52

(52) U.S. Cl. CPC H01L 51/5032; H01L 27/3211; H01L 51/5206; H01L 51/5234; H01L 27/3244; H01L 51/5281; H01L 51/0038

(57) ABSTRACT

The present invention discloses a light-emitting electrochemical cell, which includes a first electrode, a light-emitting layer, and a second electrode which are stacked, wherein the light-emitting layer includes a light-emitting material and an ion conductive polymer. The present invention also discloses an electroluminescent display device, including a glass substrate, a thin film transistor, a light-emitting electrochemical cell, a protective layer, and a polarizer. Embodiments of the present application provide a light-emitting electrochemical cell and an electroluminescence display device, wherein the electro-luminescence display device is construed by providing a simple structure and manufacturing process to the light-emitting electrochemical cell, and therefore the manufacturing cost is reduced, and the production efficiency is improved.

### BACKGROUND OF INVENTION

### Field of Invention

The present invention relates to a field of photovoltaic technology, and in particular, to a light-emitting electrochemical cell and an electroluminescent display device.

### Description of Prior Art

Electroluminescent display devices, such as organic light-emitting diodes (OLEDs) and micro light-emitting diodes (micro LEDs), are widely used in a field of display such as mobile phones, computers, watches, automotive meters, and the like, due to their wide viewing angles, high contrast, and thin device structures. Generally, an LED is mainly composed of a multilayered structure including, for example, a cathode, an electron injection layer, an electron transport layer, a light-emitting layer, a hole transport layer, a hole injection layer, and an anode, which results in a complicated process and high cost.

Compared with the traditional organic electroluminescent diode (OLED) technology, light-emitting electrochemical cells (LEC) have attracted more and more attention in the field of display and lighting due to their simple structures and manufacturing processes.

### SUMMARY OF INVENTION

The present application provides a light-emitting electrochemical cell and an electroluminescence display device. Based on a light-emitting electrochemical cell (LEC), an electroluminescence display device is constructed, and further served as a pixel unit to realize an electroluminescence display.

Embodiments of the present application provide a light-emitting electrochemical cell and an electroluminescence display device, wherein the electro-luminescence display device is construed by providing a simple structure and manufacturing process to the light-emitting electrochemical cell, and therefore the manufacturing cost is reduced, and the production efficiency is improved.

An embodiment of the present application provides a light-emitting electrochemical cell, including a first electrode, a light-emitting layer, and a second electrode which are stacked, the light-emitting layer including a light-emitting material and an ion conductive polymer;

wherein ions in the ion conductive polymer in the light-emitting layer migrate to form dopants of the light-emitting material, such that a P-N junction is formed;

wherein the light-emitting material includes a perovskite-based material, and the ion conductive polymer includes a polyoxyacetylene material; and

wherein the first electrode and the second electrode are made of inert metal materials.

According to the light-emitting electrochemical cell provided by an embodiment of the present invention, the first electrode is a cathode made of a material including indium tin oxide, a single-layered metal or a metal alloy selected from gold metal, platinum metal, silver metal, aluminum metal, lithium metal, magnesium metal, calcium metal, gallium metal, and indium metal.

According to the light-emitting electrochemical cell provided by an embodiment of the present invention, the second electrode is an anode made of a material including indium tin oxide, a single-layered metal or a metal alloy selected from gold metal, platinum metal, silver metal, aluminum metal, lithium metal, magnesium metal, calcium metal, gallium metal, and indium metal.

According to the light-emitting electrochemical cell provided by an embodiment of the present invention, the first electrode and the second electrode are made of a same material or different materials.

According to the light-emitting electrochemical cell provided by an embodiment of the present invention, the light-emitting material further includes a quantum dot-based material, a poly(1,4-phenylenevinylene) material, a poly [2-methoxy-5-(2-ethylhexyloxy)-1,4-phenylenevinylene] material, a poly(1,4-phenylene) material, a polyfluorene material, poly(thiophene) material, a poly(2,5-pyridine vinylidene) material, a conductive conjugated polymer material, or a semiconductor conjugated polymer, and derivative materials thereof.

According to the light-emitting electrochemical cell provided by an embodiment of the present invention, the ion conductive polymer further includes a polypropylene oxide material, a polyethylene succinate material, a polyethylene glycol sebacate material, a polyethylene glycol imine material, a polyether-based ionic compound material, a polyether, a polyester, or polyimide-based ion conductive polymer materials.

An embodiment of the present invention further provides a light-emitting electrochemical cell, which includes a first electrode, a light-emitting layer, and a second electrode which are stacked, the light-emitting layer including a light-emitting material and an ion conductive polymer;

wherein ions in the ion conductive polymer in the light-emitting layer migrate to form dopants of the light-emitting material, such that a P-N junction is formed; and

wherein the light-emitting material includes a perovskite-based material, and the ion conductive polymer includes a polyoxyacetylene material.

According to the light-emitting electrochemical cell provided by an embodiment of the present invention, the first electrode is a cathode made of a material including indium tin oxide, a single-layered metal or a metal alloy selected from gold metal, platinum metal, silver metal, aluminum metal, lithium metal, magnesium metal, calcium metal, gallium metal, and indium metal.

According to the light-emitting electrochemical cell provided by an embodiment of the present invention, the second electrode is an anode made of a material including indium tin oxide, a single-layered metal or a metal alloy selected from gold metal, platinum metal, silver metal, aluminum metal, lithium metal, magnesium metal, calcium metal, gallium metal, and indium metal.

According to the light-emitting electrochemical cell provided by an embodiment of the present invention, the first electrode and the second electrode are made of a same material or different materials.

According to the light-emitting electrochemical cell provided by an embodiment of the present invention, the light-emitting material further includes a quantum dot-based material, a poly(1,4-phenylenevinylene) material, a poly [2-methoxy-5-(2-ethylhexyloxy)-1,4-phenylenevinylene] material, a poly(1,4-phenylene) material, a polyfluorene material, poly(thiophene) material, a poly(2,5-pyridine vinylidene) material, a conductive conjugated polymer material, or a semiconductor conjugated polymer, and derivative materials thereof.

According to the light-emitting electrochemical cell provided by an embodiment of the present invention, the ion conductive polymer further includes a polypropylene oxide material, a polyethylene succinate material, a polyethylene glycol sebacate material, a polyethylene glycol imine material, a polyether-based ionic compound material, a polyether, a polyester, or polyimide-based ion conductive polymer materials.

An embodiment of the present invention further provides an electroluminescence display device, which includes:

a glass substrate;

a thin film transistor disposed on a side of the glass substrate to control a supplied voltage of each pixel;

a light-emitting electrochemical cell disposed on a side of the thin-film transistor away from the glass substrate;

a protective layer disposed on a side of the light-emitting electrochemical cell away from the thin film transistor; and

a polarizer disposed on a side of the protective layer away from the light-emitting electrochemical cell,

wherein the light-emitting electrochemical cell is the light-emitting electrochemical cell according to claim 1.

According to an electroluminescent display device provided by an embodiment of the present invention, the light-emitting electrochemical cell includes a red light-emitting electrochemical cell, a green light-emitting electrochemical cell, and a blue light-emitting electrochemical cell.

According to an electroluminescent display device provided by an embodiment of the present invention, the light-emitting electrochemical cell includes a first electrode made of a material including indium tin oxide, a single-layered metal or a metal alloy selected from gold metal, platinum metal, silver metal, aluminum metal, lithium metal, magnesium metal, calcium metal, gallium metal, and indium metal.

According to an electroluminescent display device provided by an embodiment of the present invention, the light-emitting electrochemical cell includes a second electrode, the second electrode is made of indium tin oxide, a silver nanowire, or a poly(3,4-ethylenedioxythiophene) material.

Compared with the prior art, the present application provides a light-emitting electrochemical cell and an electroluminescence display device, wherein difference in mechanism between a light-emitting electrochemical cell and an organic electroluminescent diode is mainly that in the light-emitting electrochemical cell, freely moving ions play a leading role in light-emitting, but directional movement of carriers of different polarities plays a leading role in organic electroluminescent diodes. The light-emitting electrochemical cell itself has the characteristics of ion mobility, and has a lower lighting voltage, a simpler device structure, and introduction of air-stable metals as electrodes compared with the organic electroluminescent diode. In the present invention, a light-emitting electrochemical cell is used to construct an electroluminescence display device, which is further served as a pixel unit to realize an electroluminescence display. By selecting fluorescent materials with different light-emitting ranges, red, green and blue light emission can be realized respectively, to achieve a full-color display. The display device has only a three-layered structure of a cathode, a light-emitting layer, and an anode, such that the structure is simple, the preparation is convenient, work function matching is not required between the electrode and the light-emitting layer, a wide variety of electrodes can be selected, and inert metals can be employed.

### BRIEF DESCRIPTION OF DRAWINGS

The specific embodiments of the present application will be described details in the following with reference to the accompanying drawings in the embodiments, making the technical solutions and other beneficial effects of the present application obvious.

FIG. 1 is a schematic structural diagram of a light-emitting electrochemical cell according to an embodiment of the present invention.

FIG. 2 is a schematic structural diagram of an electroluminescent display device according to an embodiment of the present invention.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application.

In the description of the present invention, it is to be understood that the terms “center”, “longitudinal”, “transverse”, “length”, “width”, “thickness”, “upper”, “lower”, “front”, “post”, “left”, “right”, “vertical”, “horizontal”, “top”, “bottom”, “inside”, “outside”, etc. demonstrating the orientation or positional relationship of the indications is based on the orientation shown in the drawings Or, the positional relationship is merely for the convenience of the description of the present invention and the simplification of the description, and is not intended to imply that the device or the component of the present invention has a specific orientation and is constructed and operated in a specific orientation, thus being not to be construed as limiting the present invention. Moreover, the terms “first” and “second” are used for descriptive purposes only and are not to be construed as indicating or implying a relative importance or not to implicitly indicate a number of technical features indicated. Thus, features defined by “first” or “second” may include one or more of the described features either explicitly or implicitly. In the description of the present invention, the meaning of “a plurality” is two or more unless specifically defined otherwise.

In the description of the present invention, it should be noted that the terms “installation”, “connection”, and “bonding” are to be understood broadly unless otherwise explicitly defined and limited. For example, it may be fixed connection, detachable connection, or integrally connection; being mechanical or electrical connection; also, being directly connection, indirectly connection through an intermediate medium, or internal communication of two components. The specific meaning of the above terms in the present invention can be understood in a specific case by those skilled in the art.

In the present invention, unless otherwise expressly stated and limited, the formation of a first feature over or under a second feature in the description that follows may include embodiments in which the first and second features are formed in direct contact, and may also include embodiments in which additional features may be formed between the first and second features, such that the first and second features may not be in direct contact. Moreover, the first feature “above”, “over” and “on” the second feature includes the first feature directly above and above the second feature, or merely indicating that the first feature is at a level higher than the second feature. The first feature “below”, “under” and “beneath” the second feature includes the first feature directly below and obliquely below the second feature, or merely the first feature has a level lower than the second feature.

The following disclosure provides many different embodiments or examples for implementing different structures of the present invention. In order to simplify the disclosure of the present invention, the components and arrangements of the specific examples are described below. Of course, they are merely examples and are not intended to limit the present invention. In addition, the present invention may repeat reference numerals and/or reference letters in the various embodiments, which are for the purpose of simplicity and clarity, and do not indicate the relationship between the various embodiments and/or arrangements discussed. Moreover, the present invention provides examples of various specific processes and materials, but one of ordinary skill in the art will recognize the use of other processes and/or the use of other materials.

Embodiments of the present application provide a light-emitting electrochemical cell and an electroluminescence display device, wherein the electro-luminescence display device is construed by providing a simple structure and manufacturing process to the light-emitting electrochemical cell, and therefore the manufacturing cost is reduced, and the production efficiency is improved.

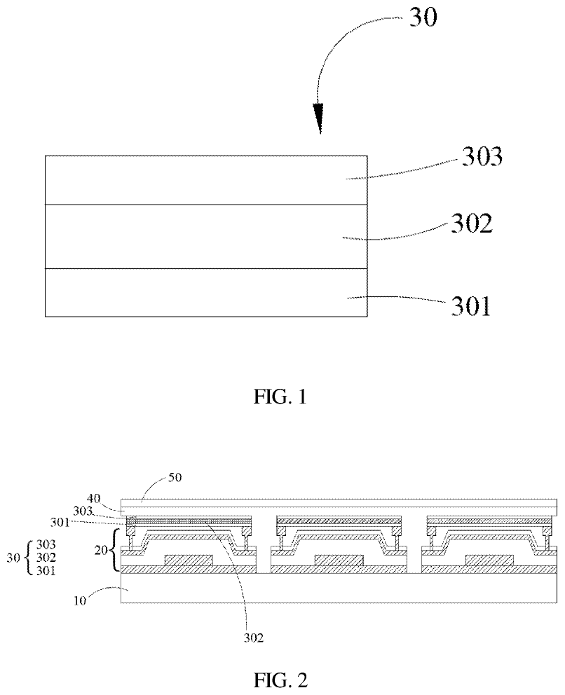

FIG. 1 is a schematic structural diagram of a light-emitting electrochemical cell 30 according to an embodiment of the present invention. As shown in FIG. 1. an embodiment of the present application provides a light-emitting electrochemical cell 30, including: a first electrode 301, a light-emitting layer 302, and a second electrode 303 which are stacked, the light-emitting layer 302 including a light-emitting material and an ion conductive polymer; wherein ions in the ion conductive polymer in the light-emitting layer 302 migrate to form dopants of the light-emitting material, such that a P-N junction is formed;

In this embodiment, the light-emitting electrochemical cell 30 is mainly composed of the first electrode 301, the light-emitting layer 302, and the second electrode 303. The light-emitting layer 302 is doped with a polymer electrolyte. The light-emitting principle of the light-emitting electrochemical cell 30 is that ions in the ion conductive polymer in the light-emitting layer 302 migrate to form dopants of the light-emitting material, such that a P-N junction is formed. Therefore, an electrode has little to do with the light-emitting properties and electrical properties of the light-emitting electrochemical cell 30. Therefore, in this embodiment, the electrode material of the light-emitting electrochemical cell 30 has more choices, and materials such as inert metals can be selected to serve as the electrode material, which can effectively prevent the electrode from being oxidized.

In the light-emitting electrochemical cell 30 provided in an embodiment of the present invention, the first electrode 301 is a cathode made of a material including indium tin oxide (ITO), a single-layered metal or a metal alloy selected from gold metal (Au), platinum metal (Pt), silver metal (Ag), aluminum metal (Al), lithium metal (Li), magnesium metal (Mg), calcium metal (Ca), gallium metal (Ga), and indium metal (In).

In the light-emitting electrochemical cell 30 provided in the embodiment of the present invention, the second electrode 303 is an anode made of a material including indium tin oxide (ITO), a single-layered metal or a metal alloy selected from gold metal (Au), platinum metal (Pt), silver metal (Ag), aluminum metal (Al), lithium metal (Li), magnesium metal (Mg), calcium metal (Ca), gallium metal (Ga), and indium metal (In).

The first electrode 301 and the second electrode 303 are made of a same material or different materials.

In the light-emitting electrochemical cell 30 provided in the embodiment of the present invention, the light-emitting layer 302 includes a light-emitting material and an ion conductive polymer; wherein the light-emitting material includes a quantum dot-based material, a poly(1,4-phenylenevinylene) material, a poly [2-methoxy-5-(2-ethylhexyloxy)-1,4-phenylenevinylene] material, a poly(1,4-phenylene) material, a polyfluorene material, poly(thiophene) material, a poly(2,5-pyridine vinylidene) material, a conductive conjugated polymer material, or a semiconductor conjugated polymer, and derivative materials thereof, and wherein the ion conductive polymer includes a polypropylene oxide material, a polyethylene succinate material, a polyethylene glycol sebacate material, a polyethylene glycol imine material, a polyether-based ionic compound material, a polyether, a polyester, or polyimide-based ion conductive polymer materials.

An embodiment of the present invention also provides a pixel unit, which is constructed based on the light-emitting electrochemical cell provided in this embodiment, and red, green and blue light emission can be realized respectively by selecting fluorescent materials with different light-emitting ranges. The pixel unit includes a thin-film field-effect transistor and the light-emitting electrochemical cell disposed above the thin-film field-effect transistor. The voltage applied to the pixel is controlled by constructing a structure of the pixelized thin film field-effect transistor, and a pixelized metal material is processed on the thin film field-effect transistor to serve as the first electrode of the light-emitting electrochemical cell. The first electrode is made of indium tin oxide (ITO), a single-layered metal or a metal alloy selected from gold metal (Au), platinum metal (Pt), silver metal (Ag), aluminum metal (Al), lithium metal (Li), magnesium metal (Mg), calcium metal (Ca), gallium metal (Ga), or indium metal (In). The light-emitting layer of the light-emitting electrochemical cell includes a light-emitting material and an ion conductive polymer; wherein the light-emitting material includes a quantum dot-based material, a poly(1,4-phenylenevinylene) material, a poly [2-methoxy-5-(2-ethylhexyloxy)-1,4-phenylenevinylene] material, a poly(1,4-phenylene) material, a polyfluorene material, poly(thiophene) material, a poly(2,5-pyridine vinylidene) material, a conductive conjugated polymer material, or a semiconductor conjugated polymer, and derivative materials thereof. The ion conductive polymer includes a polypropylene oxide material, a polyethylene succinate material, a polyethylene glycol sebacate material, a polyethylene glycol imine material, a polyether-based ionic compound material, a polyether, a polyester, or polyimide-based ion conductive polymer materials. Since the light-emitting layer is mainly composed of an electroluminescent material and an ion conductive polymer electrolyte, the solution of this system is very suitable for solution processing. Therefore, ink-jet printing technology can be used to print red, green, and blue light-emitting materials on the pixel electrodes to form the light-emitting layer, and then transparent electrodes such as indium tin oxide (ITO), silver nanowires, poly(3,4-ethylenedioxythiophene) materials (PEDOT), or a single-layered metal or a metal alloy selected from gold metal (Au), platinum metal (Pt), silver metal (Ag), aluminum metal (Al), lithium metal (Li), magnesium metal (Mg), calcium metal (Ca), gallium metal (Ga), or indium metal (In) is processed to serve as the second electrode of the light-emitting electrochemical cell.

An embodiment of the present invention further provides an electroluminescence display device, which is constructed based on the light-emitting electrochemical cell provided in this embodiment to serve as a pixel unit, such that electroluminescence display is realized. By selecting fluorescent materials with different light-emitting ranges, red, green and blue light emission can be realized respectively, and then a full-color display can be obtained. The display device has only a three-layered structure of a cathode, a light-emitting layer, and an anode, such that the structure is simple, the preparation is convenient, no matching function is required between the electrode and the light-emitting layer, electrode selectivity, and inert metals can be employed

FIG. 2 is a schematic structural diagram of an electroluminescent display device according to an embodiment of the present invention. As shown in FIG. 2, the electroluminescent display device includes: a glass substrate 10; a thin film transistor 20 disposed on a side of the glass substrate 10 to control a supplied voltage of each pixel; a light-emitting electrochemical cell 30 disposed on a side of the thin-film transistor 20 away from the glass substrate 10; a protective layer 40 disposed on a side of the light-emitting electrochemical cell 30 away from the thin film transistor 20; and a polarizer 50 disposed on a side of the protective layer 40 away from the light-emitting electrochemical cell 30, wherein the light-emitting electrochemical cell 30 is the light-emitting electrochemical cell provided in an embodiment of the present invention.

As shown in FIG. 2, the voltage applied to the pixel is controlled by constructing a structure of the pixelized thin film transistor 20, and a pixelized metal material is processed on the thin film transistor 20 to serve as the first electrode 301 of the light-emitting electrochemical cell 30. The first electrode is made of indium tin oxide (ITO), a single-layered metal or a metal alloy selected from gold metal (Au), platinum metal (Pt), silver metal (Ag), aluminum metal (Al), lithium metal (Li), magnesium metal (Mg), calcium metal (Ca), gallium metal (Ga), or indium metal (In). The light-emitting layer of the light-emitting electrochemical cell includes a light-emitting material and an ion conductive polymer; wherein the light-emitting material includes a quantum dot-based material, a poly(1,4-phenylenevinylene) material, a poly [2-methoxy-5-(2-ethylhexyloxy)-1,4-phenylenevinylene] material, a poly(1,4-phenylene) material, a polyfluorene material, poly(thiophene) material, a poly(2,5-pyridine vinylidene) material, a conductive conjugated polymer material, or a semiconductor conjugated polymer, and derivative materials thereof. The ion-conductive polymer includes a polypropylene oxide material, a polyethylene succinate material, a polyethylene glycol sebacate material, a polyethylene glycol imine material, a polyether-based ionic compound material, a polyether, a polyester, or polyimide-based ion conductive polymer materials. Since the light-emitting layer 302 is mainly composed of an electroluminescent material and an ion conductive polymer electrolyte, the solution of this system is very suitable for solution processing. Therefore, ink-jet printing technology can be used to print red, green, and blue light-emitting materials on the pixel electrodes to form the light-emitting layer 302, and then transparent electrodes such as indium tin oxide (ITO), silver nanowires, poly(3,4-ethylenedioxythiophene) materials (PEDOT), or a single-layered metal or a metal alloy selected from gold metal (Au), platinum metal (Pt), silver metal (Ag), aluminum metal (Al), lithium metal (Li), magnesium metal (Mg), calcium metal (Ca), gallium metal (Ga), or indium metal (In) is processed to serve as the second electrode of the light-emitting electrochemical cell. The light-emitting electrochemical cell 30 includes a red light-emitting electrochemical cell, a green light-emitting electrochemical cell, and a blue light-emitting electrochemical cell. In FIG. 2, the components from left to right are a red light-emitting electrochemical cell that emits red light, a green light-emitting electrochemical cell that emits green light, and a blue light-emitting electrochemical cell that emits blue light. Finally, a protective layer 40 is formed on the second electrode 303 to protect the light-emitting device, and a structure such as a polarizer 50 is formed on the protective layer 40 to reduce light reflection of the light-emitting device.

Difference in mechanism between a light-emitting electrochemical cell and an organic electroluminescent diode is mainly that in the light-emitting electrochemical cell, freely moving ions play a leading role in light-emitting, but directional movement of carriers of different polarities plays a leading role in organic electroluminescent diodes. The light-emitting electrochemical cell itself has the characteristics of ion mobility, and has a lower lighting voltage, a simpler device structure, and introduction of air-stable metals as electrodes compared with the organic electroluminescent diode. In the present invention, a light-emitting electrochemical cell is used to construct an electroluminescence display device, which is further served as a pixel unit to realize an electroluminescence display. By selecting fluorescent materials with different light-emitting ranges, red, green and blue light emission can be realized respectively, to achieve a full-color display. The display device has only a three-layered structure of a cathode, a light-emitting layer, and an anode, such that the structure is simple, the preparation is convenient, work function matching is not required between the electrode and the light-emitting layer, a wide variety of electrodes can be selected, and inert metals can be employed.

The light-emitting electrochemical cell and the electroluminescence display device provided in the embodiments of the present application have been described in detail above. Specific examples are used in this document to explain the principles and implementation of the present invention. The descriptions of the above embodiments are only for understanding the method of the present invention and its core ideas, to help understand the technical solution of the present application and its core ideas, and a person of ordinary skill in the art should understand that it can still modify the technical solution described in the foregoing embodiments, or equivalently replace some of the technical features. Such modifications or replacements do not depart the spirit of the corresponding technical solutions beyond the scope of the technical solutions of the embodiments of the present application.

What is claimed is:

1. A light-emitting electrochemical cell, comprising a first electrode, a light-emitting layer, and a second electrode which are stacked, the light-emitting layer comprising a light-emitting material and an ion conductive polymer;
wherein ions in the ion conductive polymer in the light-emitting layer migrate to form dopants of the light-emitting material, such that a P-N junction is formed;
wherein the light-emitting material comprises a perovskite-based material, and the ion conductive polymer comprises a polyoxyacetylene material; and
wherein the first electrode and the second electrode are made of inert metal materials.

2. The light-emitting electrochemical cell according to claim 1, wherein the first electrode is a cathode made of a material comprising indium tin oxide, a single-layered metal or a metal alloy selected from gold metal, platinum metal, silver metal, aluminum metal, lithium metal, magnesium metal, calcium metal, gallium metal, and indium metal.

3. The light-emitting electrochemical cell according to claim 1, wherein the second electrode is an anode made of a material comprising indium tin oxide, a single-layered metal or a metal alloy selected from gold metal, platinum metal, silver metal, aluminum metal, lithium metal, magnesium metal, calcium metal, gallium metal, and indium metal.

4. The light-emitting electrochemical cell according to claim 3, wherein the first electrode and the second electrode are made of a same material or different materials.

5. The light-emitting electrochemical cell according to claim 1, wherein the light-emitting material further comprises a quantum dot-based material, a poly(1,4-phenylenevinylene) material, a poly [2-methoxy-5-(2-ethylhexyloxy)-1,4-phenylenevinylenel] material, a poly(1,4-phenylene) material, a polyfluorene material, poly(thiophene) material, a poly(2,5-pyridine vinylidene) material, a conductive conjugated polymer material, or a semiconductor conjugated polymer, and derivative materials thereof.

6. The light-emitting electrochemical cell according to claim 1, wherein the ion conductive polymer further comprises a polypropylene oxide material, a polyethylene succinate material, a polyethylene glycol sebacate material, a polyethylene glycol imine material, a polyether-based ionic compound material, a polyether, a polyester, or polyimide-based ion conductive polymer materials.

7. A light-emitting electrochemical cell, comprising a first electrode, a light-emitting layer, and a second electrode which are stacked, the light-emitting layer comprising a light-emitting material and an ion conductive polymer;
wherein ions in the ion conductive polymer in the light-emitting layer migrate to form dopants of the light-emitting material, such that a P-N junction is formed; and
wherein the light-emitting material comprises a perovskite-based material, and the ion conductive polymer comprises a polyoxyacetylene material.

8. The light-emitting electrochemical cell according to claim 7, wherein the first electrode is a cathode made of a material comprising indium tin oxide, a single-layered metal or a metal alloy selected from gold metal, platinum metal, silver metal, aluminum metal, lithium metal, magnesium metal, calcium metal, gallium metal, and indium metal.

9. The light-emitting electrochemical cell according to claim 7, wherein the second electrode is an anode made of a material comprising indium tin oxide, a single-layered metal or a metal alloy selected from gold metal, platinum metal, silver metal, aluminum metal, lithium metal, magnesium metal, calcium metal, gallium metal, and indium metal.

10. The light-emitting electrochemical cell according to claim 9, wherein the first electrode and the second electrode are made of a same material or different materials.

11. The light-emitting electrochemical cell according to claim 7, wherein the light-emitting material further comprises a quantum dot-based material, a poly(1,4-phenylenevinylene) material, a poly [2-methoxy-5-(2-ethylhexyloxy)-1,4-phenylenevinylenel] material, a poly(1,4-phenylene) material, a polyfluorene material, poly(thiophene) material, a poly(2,5-pyridine vinylidene) material, a conductive conjugated polymer material, or a semiconductor conjugated polymer, and derivative materials thereof.

12. The light-emitting electrochemical cell according to claim 7, wherein the ion conductive polymer further comprises a polypropylene oxide material, a polyethylene succinate material, a polyethylene glycol sebacate material, a polyethylene glycol imine material, a polyether-based ionic compound material, a polyether, a polyester, or polyimide-based ion conductive polymer materials.

13. An electroluminescent display device, comprising:
a glass substrate;
a thin film transistor disposed on a side of the glass substrate to control a supplied voltage of each pixel;
a light-emitting electrochemical cell disposed on a side of the thin-film transistor away from the glass substrate;
a protective layer disposed on a side of the light-emitting electrochemical cell away from the thin film transistor; and
a polarizer disposed on a side of the protective layer away from the light-emitting electrochemical cell,
wherein the light-emitting electrochemical cell is the light-emitting electrochemical cell according to claim 1.

14. The electroluminescence display device according to claim 13, wherein the light-emitting electrochemical cell comprises a red light-emitting electrochemical cell, a green light-emitting electrochemical cell, and a blue light-emitting electrochemical cell.

15. The electroluminescent display device according to claim 13, wherein the light-emitting electrochemical cell comprises a first electrode made of a material comprising indium tin oxide, a single-layered metal or a metal alloy selected from gold metal, platinum metal, silver metal, aluminum metal, lithium metal, magnesium metal, calcium metal, gallium metal, and indium metal.

16. The electroluminescent display device according to claim 15, wherein the light-emitting electrochemical cell comprises a second electrode, the second electrode is made of indium tin oxide, a silver nanowire, or a poly(3,4-ethylenedioxythiophene) material.
